(19) United States
(12) Patent Application Publication
(10) Pub. No.: US 2026/0052978 A1
(43) Pub. Date: Feb. 19, 2026

(54) INTEGRATED CIRCUITS (IC)

(71) Applicant: Samsung Electronics Co., Ltd., Suwon-si (KR)

(72) Inventors: Panjae Park, Suwon-si (KR); Subin Choi, Suwon-si (KR)

(21) Appl. No.: 19/012,012

(22) Filed: Jan. 7, 2025

(30) Foreign Application Priority Data
Aug. 13, 2024 (KR) 10-2024-0108571

(51) Int. Cl. H01L 23/528; H01L 23/522; H10D 89/10

(52) U.S. Cl. CPC H01L 23/5283; H01L 23/5226; H10D 89/10

(57) ABSTRACT

An integrated circuit (IC) includes a plurality of first layers extending in a first direction and disposed in a second direction perpendicular to the first direction, and a second layer including a first unit layer extending in a third direction intersecting the first direction and the second direction, and a second unit layer connected to the first unit layer and extending in a fourth direction symmetrical to the third direction with respect to the first direction, and electrically connected to the one first layer through a first via positioned in one of the plurality of first layers.

### CROSS-REFERENCE TO RELATED APPLICATION

This application claims priority under 35 U.S.C. Section 119 to, and the benefit of, Korean Patent Application No. 10-2024-0108571 filed in the Korean Intellectual Property Office on Aug. 13, 2024, the entire contents of which are incorporated herein by reference.

### FIELD

The present disclosure related to integrated circuits and methods for manufacturing the same.

### BACKGROUND

An integrated circuit (IC) that processes digital signals may be designed based on standard cells. A functional circuit may be formed by arranging and routing standard cells so that the IC implements a desired function.

Meanwhile, as the demand for high performance, high speed, and/or multifunctionalization for the IC increases, the degree of integration of the IC is increasing. According to the tendency of high integration of ICs, there is a problem that spacing between routing layers and vias are reduced, which reduces a process margin.

### SUMMARY

The present disclosure provides an integrated circuit (IC) capable of increasing a process margin.

The present disclosure provides an IC capable of reducing process cost.

An integrated circuit (IC) according to some embodiments includes a plurality of first layers extending in a first direction and disposed in a second direction perpendicular to the first direction, and a second layer including a first unit layer extending in a third direction intersecting the first direction and the second direction, and a second unit layer connected to the first unit layer and extending in a fourth direction symmetrical to the third direction with respect to the first direction, and electrically connected to one layer of the plurality of first layers through a first via positioned in the one layer.

An IC according to some embodiments includes a standard cell including a plurality of cell boundaries extending in a first direction, a first layer extending in the first direction between a first cell boundary and a second cell boundary among the plurality of cell boundaries, and a second layer extending from a first point of the first cell boundary to a second point spaced apart from the first point by a first length in the first direction and positioned between the first cell boundary and the second cell boundary in a second direction perpendicular to the first direction, wherein the second layer is symmetrical in the second direction on the standard cell, and the second layer is positioned on the first layer.

An IC according to some embodiments includes a first standard cell, a second standard cell adjacent to the first standard cell in a first direction, a first layer extending in a second direction perpendicular to the first direction on the first standard cell and the second standard cell, and a second layer including a plurality of first unit layers positioned on the first layer on the first standard cell and the second standard cell and extending in a third direction between the first direction and the second direction, and a plurality of second unit layers symmetrical with the plurality of first unit layers in the first direction and alternately disposed with the plurality of first unit layers in the first direction.

### BRIEF DESCRIPTION OF THE DRAWINGS

FIG. 1 is a cross-sectional view of an integrated circuit (IC) according to some embodiments.

FIG. 2 is a layout diagram of a partial region of the IC according to some embodiments.

FIG. 3 is a cross-sectional view of the IC taken along line A-A′ of FIG. 2.

FIG. 4 is a cross-sectional view of the IC taken along line B-B′ of FIG. 2.

FIG. 5 is a layout diagram of the IC according to some embodiments.

FIG. 6 is a layout diagram of a standard cell and layers on the standard cell according to some embodiments.

FIG. 7 is a layout diagram of a standard cell and layers on the standard cell according to some embodiments.

FIG. 8 is a layout diagram of a partial region of an IC according to some embodiments.

FIG. 9 is a layout diagram of a partial region of an IC according to a comparative example.

FIG. 10 is a layout diagram of a partial region of an IC according to some embodiments.

FIG. 11 is a layout diagram of a standard cell and layers in the standard cell according to some embodiments.

FIG. 12 is a flowchart for explaining a method of designing and manufacturing an IC according to embodiments.

FIG. 13 is a diagram schematically illustrating a design system of an IC according to some embodiments.

### DETAILED DESCRIPTION

Hereinafter, with reference to the accompanied drawings, embodiments of the present disclosure will be described in more detail. The same reference numerals are used for the same components in the drawings, and redundant descriptions of the same components are omitted.

It should be understood that the embodiments described herein are intended to implement various features of the present disclosure. These are only examples and are not intended to be limiting. For example, the dimensions of the components are not limited to the disclosed ranges or values and may vary depending on process conditions and/or the properties of a desired device. For example, the formation of a first structure over or on a second structure in the description that follows may include embodiments in which the first and second structures are formed in direct contact, and may also include embodiments in which additional structures may be formed between the first and second structures such that the first and second structures may not be in direct contact. For simplicity and clarity, various structures may be drawn arbitrarily at different scales.

Further, spatially relative terms, such as “under,” “below,” “lower,” “over,” “upper”, etc., may be used herein for ease of description to describe one element or relationship of structures to another element or structure as illustrated in the drawings.

Additionally, ordinal numbers such as “first,” “second,” “third,” etc. may be used as labels for specific elements, steps, directions, etc. to distinguish various elements, steps, directions, etc. from each other. Terms that are not described using “first,” “second,” etc. in the specification may still be referred to as “first” or “second” in the claims. Additionally, terms (for example, “first” in a particular claim) referenced by a particular ordinal number may be described elsewhere with a different ordinal number (for example, “second” in the specification or another claim).

The terms “comprises,” “comprising,” “includes” and/or “including,” when used herein, specify the presence of stated elements, but do not preclude the presence of additional elements.

The term “and/or” includes any and all combinations of one or more of the associated listed items.

The term “connected” may be used herein to refer to a physical and/or electrical connection.

Also, to clearly explain the present disclosure in the drawings, parts that are not related to the description are omitted, and similar parts are given similar reference numerals throughout the specification. In the flowchart described with reference to the drawings, an operation order may be changed, several operations may be merged, a certain operation may be divided, and a specific operation may not be performed.

Also, expressions described in the singular may be interpreted as singular or plural unless explicit expressions such as “one” or “single” are used. Terms that include ordinal numbers such as first, second, etc. may be used to describe various components, but the components are not limited by these terms. These terms may be used for the purpose of distinguishing one component from another.

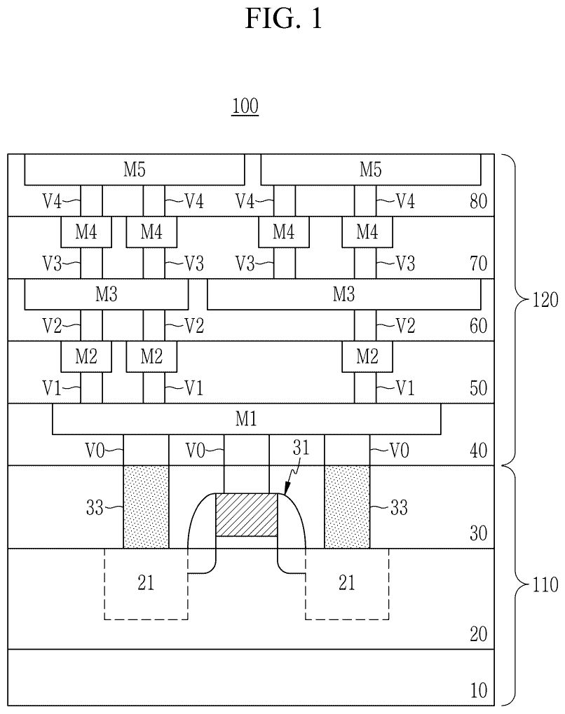

FIG. 1 is a cross-sectional view of an integrated circuit (IC) 100 according to some embodiments.

In some embodiments, the IC 100 may include a front-end-of-line (FEOL) region 110 and a back-end-of-line (BEOL) region 120. Specifically, the FEOL region 110 may correspond to a region including various layers and patterns necessary for a function of an active semiconductor device (i.e., a transistor used to transmit/process a signal) in the IC 100, and the BEOL region 120 may correspond to a region including a routing layer electrically connecting semiconductor devices.

Referring to FIG. 1, the FEOL region 110 may include a substrate 10. The substrate 10 may be a P-type substrate. Alternatively, the substrate 10 may be an N-type substrate.

The FEOL region 110 may include an active region 20 formed on the substrate 10 and source/drain regions 21 formed on the active region 20. The FEOL region 110 may further include a gate structure 31 positioned between the source/drain regions 21. The source/drain regions 21 and the gate structure 31 may form a transistor.

The FEOL region 110 may include an insulating layer 30 disposed on the active region 20 and a contact layer 33 disposed on the insulating layer 30. The contact layer 33 may electrically contact the source/drain regions 21. The contact layer 33 may connect the source/drain regions 21 to vias V0. The source/drain regions 21 may be connected to vias V0, V1, V2, V3, and V4 and routing layers M1, M2, M3, M4, and M5 in the BEOL region 120 through the contact layer 33. The IC 100 may further include the vias V0 connected to the gate structure 31.

The BEOL region 120 may be formed over the FEOL region 110. The BEOL region 120 electrically connects semiconductor devices within the IC 100 to allow the IC 100 to operate. Specifically, the IC 100 includes a plurality of insulating layers 40, 50, 60, 70, and 80, the vias V0, V1, V2, V3, and V4 respectively formed in the insulating layers 40, 50, 60, 70, and 80, and the routing layers M1, M2, M3, M4, and M5. Each of the vias V0, V1, V2, V3, and V4 connects the routing layers M1, M2, M3, M4, and M5 positioned on different layers to each other, and connects the contact layer 33 to the routing layers M1, M2, M3, M4, and M5. The routing layers M1, M2, M3, M4, and M5 may cross and extend to each other. For example, the first routing layer M1 in the insulating layer 40 may extend in a first direction, and the second routing layer M2 in the insulating layer 50 may extend in a second direction crossing the first direction. The third routing layer M3 in the insulating layer 60 may extend in the first direction, and the fourth routing layer M4 in the insulating layer 70 may extend in the second direction. The first routing layer M1 and the third routing layer M3 extending in the first direction each may be referred to as a horizontal layer, and the second routing layer M2 and the fourth routing layer M4 extending in the second direction each may be referred to as a vertical layer. Each of the routing layers M1, M2, M3, M4, and M5 which is a conductive layer may be referred to as a metal layer. Hereinafter, for convenience of description, a routing layer will be referred to as a layer.

Meanwhile, a configuration of the IC 100 according to some embodiments is not limited thereto. For example, the IC 100 may further include an additional layer between layers, may not include some of the layers described above, may further include an additional configuration formed in each layer, or may not include some of the configurations formed in each of the layers described above. In addition, the IC 100 may include more upper layers (not shown, M6, M7, etc., which may be located on M5). A detailed description of a material of each configuration and a method of forming each configuration is omitted herein.

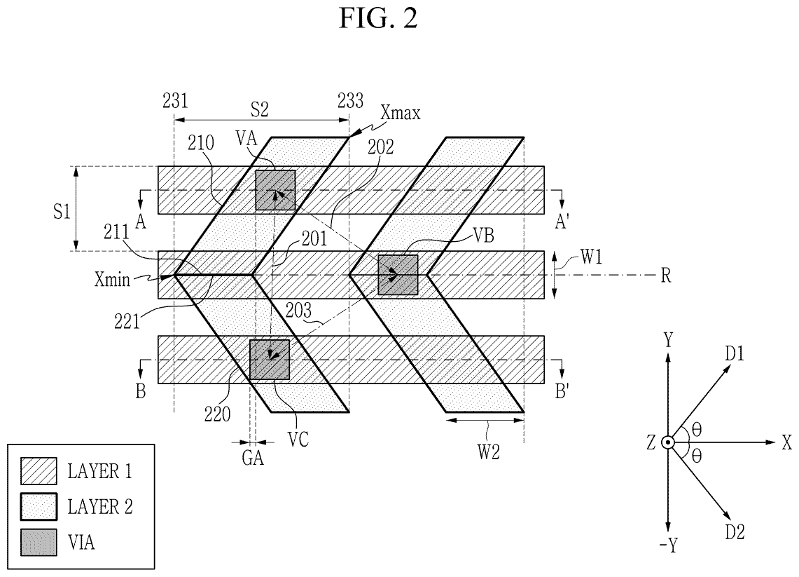

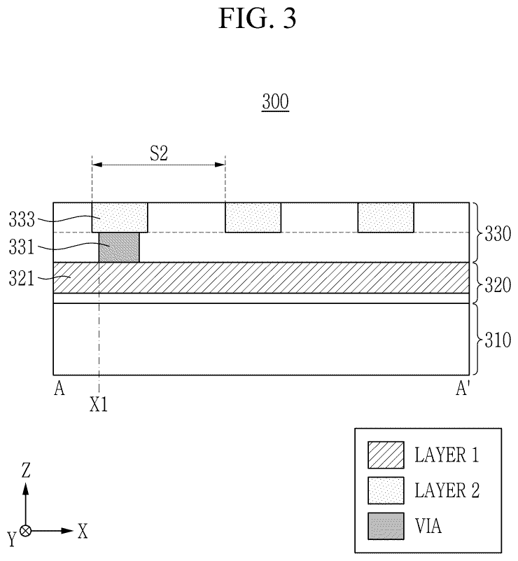

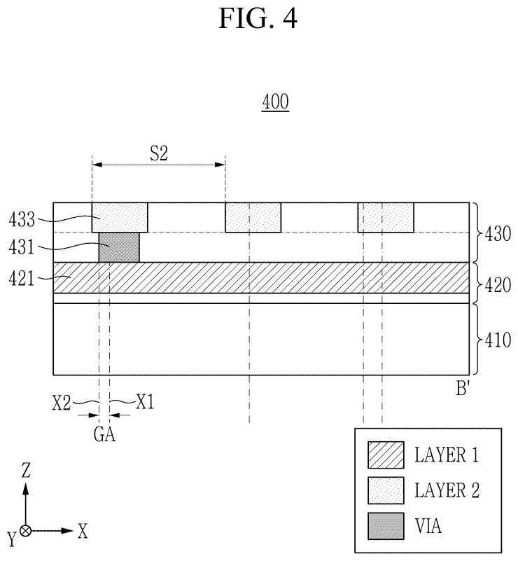

FIG. 2 is a layout diagram of a partial region of an IC 200 according to some embodiments. FIG. 3 is a cross-sectional view of an IC 300 taken along line A-A′ of FIG. 2. FIG. 4 is a cross-sectional view of an IC 400 taken along line B-B′ of FIG. 2.

Specifically, FIG. 2 is a layout diagram illustrating two layers stacked adjacent to each other among a plurality of routing layers disposed on the IC (100 of FIG. 1). For example, a first layer LAYER 1 may correspond to the first routing layer M1 of FIG. 1, and a second layer LAYER 2 may correspond to the second routing layer M2 of FIG. 1 stacked adjacent to the first routing layer M1, but the present disclosure is not limited thereto.

Referring to FIG. 2, the IC 200 may extend in a first direction (e.g., X direction) and include a plurality of first layers LAYER 1 disposed in a second direction (e.g., Y direction) perpendicular to the first direction. The plurality of first layers LAYER 1 may be parallel to each other. The plurality of first layers LAYER 1 may extend in a first direction (X) and be arranged in the second direction (Y). For example, the first layers LAYER 1 may be relatively serially distributed or disposed in or along the second direction Y (as illustrated in FIG. 2, for example). In some embodiments, the first layer LAYER 1 may have a first width W1. Here, a width of the first layer LAYER 1 may refer to a width of the first layer LAYER 1 in the second direction Y. Also, the plurality of first layers LAYER 1 may be repeated for each first length S1 in the second direction Y.

In some embodiments, the IC 200 may include a plurality of second layers LAYER 2 stacked on the first layer LAYER 1 in a vertical direction (e.g., a Z direction). In some embodiments, the second layer LAYER 2 may have a second width W2. Here, a width of the second layer LAYER 2 may refer to a width of the second layer LAYER 2 in the first direction X. Also, the plurality of second layers LAYER 2 adjacent in the first direction X may be repeated for each second length S2 in the first direction X. Here, the first width W1 and the second width W2 may be different from each other, and the first length S1 and the second length S2 may be different from each other. For example, the second width W2 may be greater than the first width W1, and the second length S2 may be greater than the first length S1, but the present disclosure is not limited thereto. Also, the first width W1 may be less than the first length S1, and the second width W2 may be less than the second length S2.

In some embodiments, the second layer LAYER 2 may include a plurality of unit layers. For example, the second layer LAYER 2 may include a first unit layer 210 and a second unit layer 220. The second layer LAYER 2 may be a layer extending in the second direction Y by alternately arranging the first unit layer 210 and the second unit layer 220 in the second direction Y (e.g., alternatingly serially distributing the first unit layer 210 and the second unit layer 220 in the second direction Y). The first unit layer 210 and the second unit layer 220 may be in contact with each other in the second direction Y and electrically connected to each other.

In some embodiments, each of the first unit layer 210 and the second unit layer 220 may extend in the second direction Y within a range of the second length S2 in the first direction X. For convenience of description, FIG. 2 illustrates a first vertical line 231 and a second vertical line 233 extending in the second direction Y in a minimum value Xmin and a maximum value Xmax among coordinate values of each of the first unit layer 210 and the second unit layer 220 in the first direction X. Specifically, the first vertical line 231 extending in the second direction Y in the minimum value Xmin of the coordinate values of each of the first unit layer 210 and the second unit layer 220 in the first direction X and the second vertical line 233 extending in the second direction Y in the maximum value Xmax of the coordinate values of each of the first unit layer 210 and the second unit layer 220 in the first direction X may be spaced apart by the second length S2 in the first direction X.

In some embodiments, each of the first vertical line 231 and the second vertical line 233 may correspond to a gate line of a transistor. That is, the second length S2 between the first vertical line 231 and the second vertical line 233 may be equal to 1 contacted poly pitch (cpp). However, the present disclosure is not limited thereto. In other embodiments, a length in the first direction X in which each unit layer is positioned may be greater or less than 1 cpp.

In some embodiments, each of the first unit layer 210 and the second unit layer 220 may extend in different directions with respect to a reference line R. Specifically, the first unit layer 210 positioned in the second direction Y from the reference line R may extend in a fourth direction D1 that intersects each of the first direction X and the second direction Y. Here, the fourth direction D1 may refer to a direction inclined at a certain angle θ from the first direction X to the second direction Y, and the certain angle θ may be, for example, 0° to 90°, but is not limited thereto. The second unit layer 220 positioned in a direction-Y opposite to the second direction Y from the reference line R may extend in a fifth direction D2 that intersects each of the first direction X and the direction-Y opposite to the second direction Y. Here, the fifth direction D2 may refer to a direction inclined at the certain angle θ from the first direction X to the direction-Y opposite to the second direction Y, and the certain angle θ may be, for example, 0° to 90°, but is not limited thereto. The fourth direction D1 and the fifth direction D2 may be symmetrical to each other in the second direction Y. The first unit layer 210 and the second unit layer 220 may be symmetrical to each other with respect to the reference line R extending in the first direction X.

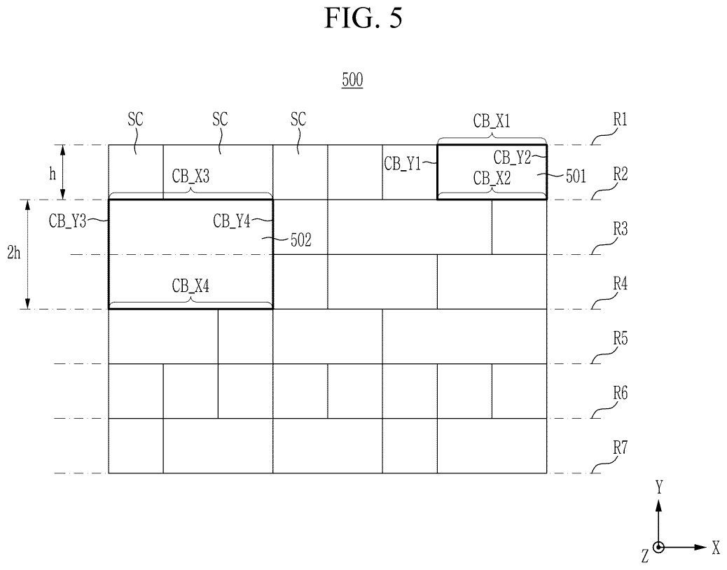

In some embodiments, a lower surface 211 of the first unit layer 210 may be in contact with the reference line R, and an upper surface 221 of the second unit layer 220 may be in contact with the reference line R. The lower surface 211 of the first unit layer 210 and the upper surface 221 of the second unit layer 220 may be in contact with each other so that the first unit layer 210 and the second unit layer 220 may be electrically connected to each other. Meanwhile, the reference line R may be repeated every certain length along the second direction Y. The length of each of the first unit layer 210 and the second unit layer 220 in the second direction Y may be equal to half of the spacing between the reference lines R adjacent to each other in the second direction Y. In some embodiments, the reference line R may correspond to a row to be described below. The row will be described in detail with reference to FIG. 5.

In some embodiments, the first layer LAYER 1 and the second layer LAYER 2 may be connected to each other through vias VIA. Each of the first layer LAYER 1, the second layer LAYER 2, and the vias VIA may be formed of metal, conductive metal nitride, metal silicide, or a combination thereof, but are not limited thereto. Referring to FIG. 2, the first layer LAYER 1 and the second layer LAYER 2 may be electrically connected to each other through first, second, and third vias VA, VB, and VC. The first, second, and third vias VA, VB, and VC may be spaced apart from each other in the first direction X and/or in the second direction Y. For example, the first via VA and the third via VC may be spaced apart by a first spacing 201, the first via VA and the second via VB may be spaced apart by a second spacing 202, and the second via VB and the third via VC may be spaced apart by a third spacing 203. The first spacing 201, the second spacing 202, and the third spacing 203 may be the same as or different from each other. According to some embodiments, the second layer LAYER 2 is disposed on the first layer LAYER 1 extending in the first direction X by extending in the fourth direction D1 inclined at the certain angle θ from the first direction X or in the fifth direction D2 inclined at a certain angle −θ from the first direction X, and thus, the first spacing 201, the second spacing 202, and the third spacing 203 of the first, second, and third vias VA, VB, and VC may be increased. Accordingly, there are advantages in that a process margin is increased and process cost is reduced.

In some embodiments, the first via VA and the third via VC may be adjacent to each other in the second direction Y. That is, the first via VA and the third via VC may be electrically connected to one second layer LAYER 2 extending in the second direction Y, and any via connected to one second layer LAYER 2 may not be positioned between the first via VA and the third via VC in the second direction Y. Positions of the first via VA and the third via VC in the first direction X may be different according to a structure of the second layer LAYER 2 according to some embodiments. A difference in the first direction X in the positions of the first via VA and the third via VC adjacent to each other in the second direction Y may be the same as a third length GA. In this regard, it will be described below with reference to FIGS. 3 and 4.

Referring to FIG. 3 (a cross-sectional view along line A-A′ of FIG. 2), the IC 300 may include a FEOL region 310 and a plurality of insulating layers 320 and 330 disposed on the FEOL region 310. The FEOL region 310 may correspond to the FEOL region 110 of FIG. 1, and the plurality of insulating layers 320 and 330 may include the first layer LAYER 1, the second layer LAYER 2, etc. A detailed description of each of the insulating layers 320 and 330 is omitted herein.

In some embodiments, a first layer 321 may extend in the first direction X. The first layer 321 may be electrically connected to a second layer 333 through a via 331 in the insulating layer 330. A plurality of second layers LAYER 2 may be repeated every second length S2 in the first direction X. Meanwhile, a position of the via 331 in the first direction X may correspond to a coordinate value X1.

Referring to FIG. 4 (a cross-sectional view along line B-B′ of FIG. 2), the IC 400 may include a FEOL region 410 and a plurality of insulating layers 420 and 430 disposed on the FEOL region 410. In some embodiments, a first layer 421 may extend in the first direction X. The first layer 421 may be electrically connected to a second layer 433 through a via 431 in the insulating layer 430. A plurality of second layers LAYER 2 may be repeated every second length S2 in the first direction X. Meanwhile, a position of the via 431 in the first direction X may correspond to a coordinate value X2.

Referring to FIGS. 2 and 3, the via 331 of FIG. 3 may correspond to the first via VA of FIG. 2, and the via 431 of FIG. 4 may correspond to the third via VC of FIG. 2. The via 331 of FIG. 3 and the via 431 of FIG. 4 may be adjacent to each other in the second direction Y. The position of the via 331 of FIG. 3 in the first direction X may correspond to the coordinate value X1, and the position of the via 431 of FIG. 4 in the first direction X may correspond to the coordinate value X2. That is, according to a structure of the second layer LAYER 2 according to some embodiments, the positions in the first direction X of the vias 331 and 431 adjacent to each other in the second direction Y may be different by the third length GA.

FIG. 5 is a layout diagram of an IC 500 according to some embodiments.

Referring to FIG. 5, the IC 500 may include a plurality of standard cells SC including circuit patterns for configuring various circuits. The plurality of standard cells SC may have functions of performing various logical functions. In some embodiments, the plurality of standard cells SC may include logical devices such as AND, OR, inverters, etc. and memory devices such as latches, flip-flops, etc., or may be one of the logical devices and the memory devices. Meanwhile, although not shown herein, the IC 500 may further include physical cells such as filler cells.

The standard cell SC may include a plurality of cell boundaries. Specifically, the standard cell SC may be defined by the plurality of cell boundaries, and a size of the standard cell SC may be determined by the plurality of cell boundaries. For example, a plurality of cell boundaries of a first standard cell 501 may include a plurality of cell boundaries CB_X1 and CB_X2 in the first direction X and a plurality of cell boundaries CB_Y1 and CB_Y2 in the second direction Y perpendicular to the first direction X. In addition, a plurality of cell boundaries of a second standard cell 502 may include a plurality of cell boundaries CB_X3 and CB_X4 in the first direction X and a plurality of cell boundaries CB_Y3 and CB_Y4 in the second direction Y.

The plurality of standard cells SC on the IC 500 may be disposed along a plurality of predefined rows R1, R2, . . . , R7 extending in the first direction X. For example, the plurality of cell boundaries CB_X1 and CB_X2 of the first standard cell 501 in the first direction X may be disposed to overlap the first and second rows R1 and R2 of the plurality of rows R1, R2, . . . , R7. Alternatively, the plurality of cell boundaries CB_X3 and CB_X4 of the second standard cell 502 in the first direction X may be disposed to overlap the second and fourth rows R2 and R4 of the plurality of rows R1, R2, . . . , R7.

Heights of the plurality of standard cells SC in the second direction Y may be the same as or different from each other. Specifically, the heights of the plurality of standard cells SC in the second direction Y may be determined according to spacing between rows in which the plurality of cell boundaries of the corresponding standard cell in the first direction X overlap. For example, a height of the first standard cell 501 in the second direction Y may be equal to a spacing h between the first row R1 in which the cell boundary CB_X1 of the first standard cell 501 in the first direction X overlaps and the second row R2 in which the cell boundary CB_X2 in the first direction X overlaps. Hereinafter, the standard cell may be referred to as a single row cell. Alternatively, a height of the second standard cell 502 in the second direction Y may be equal to a spacing 2h between the second row R2 in which the cell boundary CB_X3 of the second standard cell 502 in the first direction X overlaps and the fourth row R4 in which the cell boundary CB_X4 in the first direction X overlaps. Hereinafter, the standard cell may be referred to as a multi-row cell. However, the present disclosure is not limited thereto, and the multi-row cell may include standard cells each having a cell height of 3 h or more.

FIG. 5 illustrates the IC 500 including the seven rows R1, R2, . . . , and R7, but this is only an example, and the IC 500 may include various numbers of rows and one row may include various numbers of standard cells.

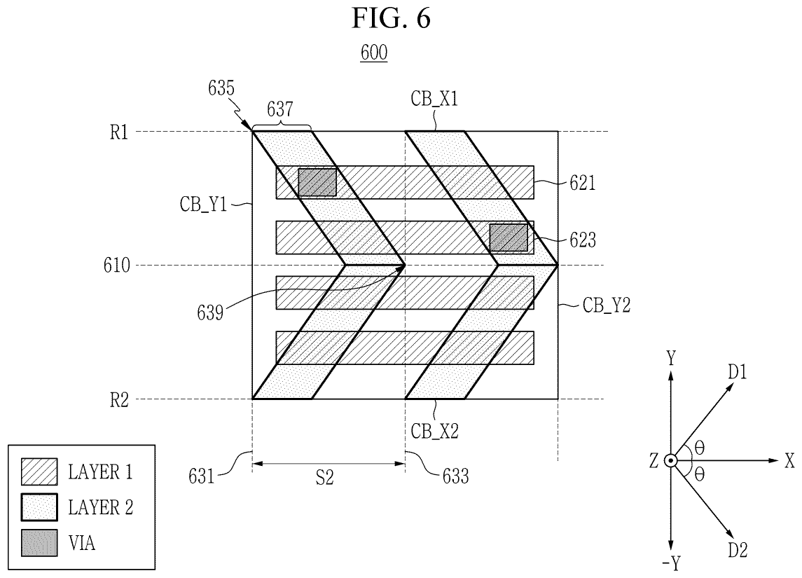

FIG. 6 is a layout diagram of a standard cell 600 and layers on the standard cell 600 according to some embodiments. Specifically, the standard cell 600 may correspond to the standard cell (501 of FIG. 5), and FIG. 6 is a diagram for explaining a structure of the second layer LAYER 2 on the standard cell 600.

Referring to FIG. 6, the standard cell 600 may include the first and second cell boundaries CB_X1 and CB_X2 extending in the first direction X and the cell boundaries CB_Y1 and CB_Y2 extending in the second direction Y. The standard cell 600 may be disposed along the first and second rows R1 and R2. Specifically, among the plurality of cell boundaries CB_X1, CB_X2, CB_Y1, and CB_Y2 of the standard cell 600, the first cell boundary CB_X1 extending in the first direction X may be disposed to overlap the first row R1, and the second cell boundary CB_X2 may be disposed to overlap the second row R2. The standard cell 600 may be a single row cell.

The standard cell 600 may include a plurality of first layers LAYER 1 extending in the first direction X. The plurality of first layers LAYER 1 may be positioned between the first cell boundary CB_X1 and the second cell boundary CB_X2 in the second direction Y. The plurality of first layers LAYER 1 may correspond to pins of the standard cell 600. For example, among the plurality of first layers LAYER 1, a layer 621 may correspond to an input pin of the standard cell 600, and a layer 623 may correspond to an output pin of the standard cell 600, but the present disclosure is not limited thereto.

The second layer LAYER 2 may be stacked (in the third direction Z) on the first layer LAYER 1. The first layer LAYER 1 and the second layer LAYER 2 may be electrically connected to each other through the via VIA positioned between the first layer LAYER 1 and the second layer LAYER 2 in the third direction Z. The second layer LAYER 2 may extend in the second direction Y within a range of the second length S2 in the first direction X. For example, the second layer LAYER 2 may extend between a first vertical line 631 corresponding to a first position in the first direction X and a second vertical line 633 corresponding to a second position in the first direction X. A detailed arrangement method and structure of the second layer LAYER 2 are the same as or similar to an arrangement method and structure of the second layer LAYER 2 of FIG. 2, and thus, detailed descriptions thereof are omitted here.

In some embodiments, the second layer LAYER 2 on the standard cell 600 may extend from the first row R1 to the second row R2. The second layer LAYER 2 on the standard cell 600 may extend from the first cell boundary CB_X1 to the second cell boundary CB_X2 of the standard cell 600. The second layer LAYER 2 on the standard cell 600 may be symmetric in the second direction Y. Specifically, the second layer LAYER 2 may be symmetric in the second direction Y with respect to a line 610 between the first row R1 and the second row R2 on which the standard cell 600 is disposed.

In some embodiments, the second layer LAYER 2 on the standard cell 600 may be in contact with a first region 637 of the first cell boundary CB_X1 at a first point 635 where the first cell boundary CB_X1 intersects with the first vertical line 631. Also, the second layer LAYER 2 may be in contact with the second vertical line 633 spaced apart from the first vertical line 631 by the second length S2 in the first direction X between the first cell boundary CB_X1 and the second cell boundary CB_X2. The second layer LAYER 2 may extend from the first point 635 where the first cell boundary CB_X1 intersects the first vertical line 631 to a second point 639 spaced apart from the first vertical line 631 by the second length S2 in the first direction X and positioned between the first cell boundary CB_X1 and the second cell boundary CB_X2. The second layer LAYER 2 may be symmetric in the second direction Y on the standard cell 600.

The second layer LAYER 2 according to some embodiments may extend in different directions with respect to the line 610. For example, the second layer LAYER 2 of the line 610 in the second direction Y may extend in the fifth direction D2 between the first direction X and the direction-Y opposite to the second direction Y. The second layer LAYER 2 of the line 610 in the direction-Y opposite to the second direction Y may extend in the fourth direction D1 between the first direction X and the second direction Y. The line 610 may be positioned in the middle of the first row R1 and the second row R2 in the second direction Y. The first row R1 and the second row R2 may be adjacent to each other in the second direction Y. That is, a length from the first row R1 to the line 610 in the second direction Y may be the same as a length from the second row R2 to the line 610.

Meanwhile, the second length S2 at which the second layer LAYER 2 extends in the first direction X may be equal to 1 cpp. However, the present disclosure is not limited thereto. In some embodiments, a length in the first direction X in which each unit layer is positioned may be greater or less than 1 cpp.

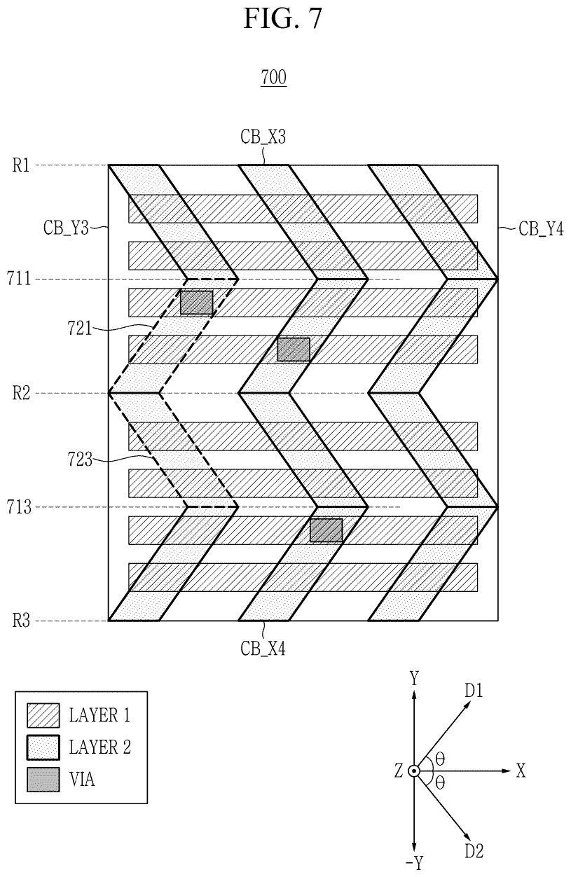

FIG. 7 is a layout diagram of a standard cell 700 and layers on the standard cell 700 according to some embodiments. Specifically, the standard cell 700 may correspond to the standard cell (502 of FIG. 5), and FIG. 7 is a diagram for explaining a structure of the second layer LAYER 2 on the standard cell 700.

Referring to FIG. 7, the standard cell 700 may include the third and fourth cell boundaries CB_X3 and CB_X4 extending in the first direction X and the cell boundaries CB_Y3 and CB_Y4 extending in the second direction Y. The standard cell 700 may be disposed along the first and third rows R1 and R3. Specifically, among the plurality of cell boundaries CB_X3, CB_X4, CB_Y3, and CB_Y4 of the standard cell 700, the third cell boundary CB_X3 extending in the first direction X may be disposed to overlap the first row R1, and the fourth cell boundary CB_X4 may be disposed to overlap the third row R3. The second row R2 may be disposed between the first row R1 and the third row R3 in the second direction Y. A length from the first row R1 to the second row R2 in the second direction Y may be the same as a length from the third row R3 to the second row R2. The standard cell 700 may be a multi row cell.

The standard cell 700 may include a plurality of first layers LAYER 1 extending in the first direction X. The plurality of first layers LAYER 1 may correspond to pins of the standard cell 700. The first layer LAYER 1 positioned on the standard cell 700 is similar to or the same as the first layer LAYER 1 positioned on the standard cell 600 of FIG. 6, and thus, a detailed description thereof is omitted here.

The second layer LAYER 2 may be stacked (in the third direction Z) on the first layer LAYER 1. The first layer LAYER 1 and the second layer LAYER 2 may be electrically connected to each other through the via VIA. In some embodiments, the second layer LAYER 2 on the standard cell 700 may extend from the first row R1 to the third row R3. The second layer LAYER 2 on the standard cell 700 may extend from the third cell boundary CB_X3 to the fourth cell boundary CB_X4. The second layer LAYER 2 on the standard cell 700 may be symmetric in the second direction Y. Specifically, the second layer LAYER 2 may be symmetric with respect to the second row R2 positioned in the middle of the third cell boundary CB_X3 and the fourth cell boundary CB_X4 in the second direction Y.

In some embodiments, the second row R2 may correspond to the reference line R of FIG. 2. That is, the second layer LAYER 2 may include a first unit layer 721 positioned in the second direction Y with respect to the second row R2 and a second unit layer 723 positioned in the direction-Y opposite to the second direction Y. The first unit layer 721 may extend from the second row R2 in the fourth direction D1 between the first direction X and the second direction Y, and the second unit layer 723 may extend in the fifth direction D2 between the first direction X and the direction-Y opposite to the second direction Y.

In some embodiments, a length of each of the first unit layer 721 and the second unit layer 723 in the second direction Y may be equal to half of the spacing between adjacent rows in the second direction Y. Specifically, a first line 711 may be positioned in the middle of the first row R1 and the second row R2 in the second direction Y, and the first unit layer 721 may extend from the second row R2 to the first line 711 in the second direction Y. A second line 713 may be positioned in the middle of the second row R2 and the third row R3 in the second direction Y, and the second unit layer 723 may extend from the second row R2 to the second line 713 in the second direction Y. The first unit layer 721 and the second unit layer 723 may be symmetrical to each other with respect to the second row R2, and the first unit layer 721 and the second unit layer 723 may be alternately disposed on the standard cell 700 in the second direction Y. In some embodiments, the length of each of the first unit layer 721 and the second unit layer 723 in the second direction Y may be equal to ¼ of a distance between the third and fourth cell boundaries CB_X3 and CB_X4 extending in the first direction X. On the standard cell 700, the length of each of the first unit layer 721 and the second unit layer 723 in the second direction Y may be equal to ½n (n is a natural number) of the distance between the third and fourth cell boundaries CB_X3 and CB_X4 extending in the first direction X.

According to some embodiments, the second layer LAYER 2 extending between cell boundaries in the first direction X of the standard cell 700 may be symmetric in the second direction Y on the standard cell 700. The second layer LAYER 2 according to some embodiments may include unit layers extending in different directions with respect to a row on an IC, and each unit layer may be symmetric in the second direction Y with respect to the row. The second layer LAYER 2 according to some embodiments may extend in the second direction Y by alternately arranging a plurality of unit layers in the second direction Y (e.g., alternatingly serially distributing the unit layers in the second direction Y). The number of first unit layers 721 and the number of second unit layers 723 on the standard cell 700 may be the same.

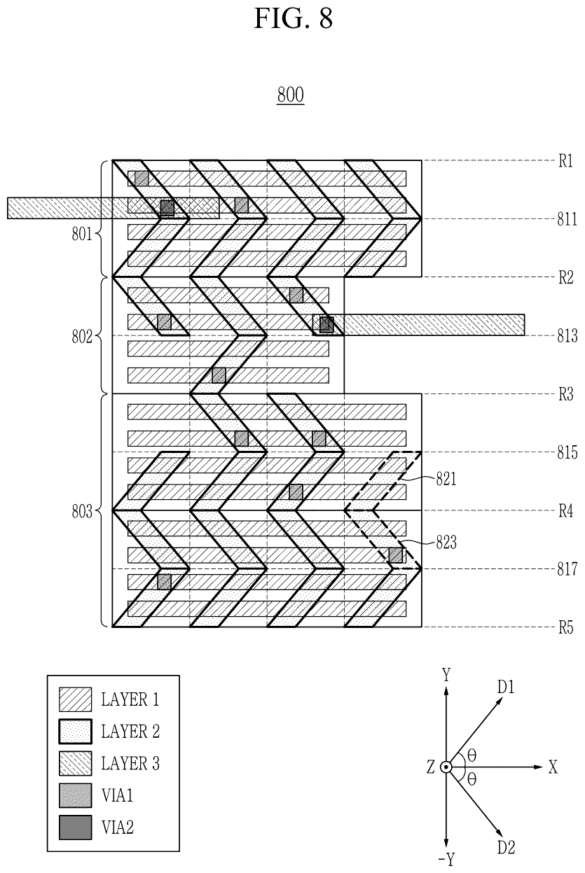

FIG. 8 is a layout diagram of a partial region of an IC 800 according to some embodiments. Specifically, FIG. 8 is a layout diagram illustrating standard cells positioned on the IC 800 and layers positioned on the standard cells.

Referring to FIG. 8, the IC 800 may include a first standard cell 801, a second standard cell 802, and a third standard cell 803. Each of the first to third standard cells 801, 802, and 803 may be disposed along a row. Specifically, the first standard cell 801 may be disposed along the first row R1 and the second row R2, the second standard cell 802 may be disposed along the second row R2 and the third row R3, and the third standard cell 803 may be disposed along the third row R3 and a fifth row R5. The first standard cell 801 and the second standard cell 802 may be single row cells, and the third standard cell 803 may be a multi row cell.

In some embodiments, a part of the second layer LAYER 2 may extend on a standard cell through a cell boundary in the first direction X of the standard cell. Specifically, the second layer LAYER 2 on the first standard cell 801 may extend from the first row R1 to the second row R2. The first row R1 and the second row R2 may overlap cell boundaries of the first standard cell 801 in the first direction X, respectively. The second layer LAYER 2 on the first standard cell 801 may be symmetric in the second direction Y.

In some embodiments, the second layer LAYER 2 may include a plurality of unit layers extending in different directions with respect to rows. For example, a first unit layer 821 positioned in the second direction Y with respect to the fourth row R4 may extend in the fourth direction D1 between the first direction X and the second direction Y, and a second unit layer 823 positioned in the direction-Y opposite to the second direction Y with respect to the fourth row R4 may extend in the fifth direction D2 between the first direction X and the direction-Y opposite to the second direction Y. A length of each of the first and second unit layers 821 and 823 in the second direction Y may be equal to half (e.g., a length from a line 815 to R4) of a length between adjacent rows (e.g., R3 and R4) in the second direction Y, and the first unit layer 821 and the second unit layer 823 may be symmetrical to each other in the second direction Y with respect to the fourth row R4. The second layer LAYER 2 may be a layer extending in the second direction Y by alternately arranging a certain number of first unit layers 821 and second unit layers 823 in the second direction Y (e.g., alternatingly serially distributing the first unit layers 821 and second unit layers 823 in the second direction Y).

The structure of the second layer LAYER 2 may be applied regardless of sizes of standard cells (e.g., single low cells or multi low cells) disposed on the IC.

Meanwhile, the first layer LAYER 1 may be electrically connected to the second layer LAYER 2 through a via VIA 1 positioned on the first layer LAYER 1, and the second layer LAYER 2 may be electrically connected to a third layer LAYER 3 through a via VIA 2 positioned on the second layer LAYER 2.

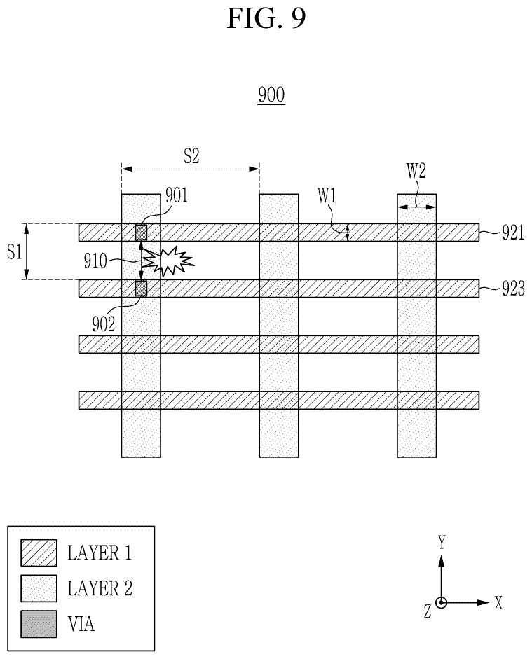

FIG. 9 is a layout diagram of a partial region of an IC 900 according to a comparative example. Specifically, FIG. 9 is a layout diagram illustrating two layers stacked adjacent to each other among a plurality of layers disposed on the IC 900 according to the comparative example. For example, the first layer LAYER 1 may correspond to the first routing layer (M1 in FIG. 1), and the second layer LAYER 2 may correspond to the second routing layer (M2 in FIG. 1) stacked (in the third direction Z) adjacent to the first routing layer M1, but the present disclosure is not limited thereto.

The IC 900 according to the comparative example may include a plurality of first layers LAYER 1 extending in the first direction X and be positioned in the second direction Y. The plurality of first layers LAYER 1 may be parallel to each other. The plurality of first layers LAYER 1 may be repeated for each first length S1 in the second direction Y. The first layer LAYER 1 may have the first width W1.

The IC 900 according to the comparative example may include the second layers LAYER 2 stacked on the first layers LAYER 1 in the vertical direction Z. The plurality of second layers LAYER 2 may extend in the second direction Y and be positioned in the first direction X. The plurality of second layers LAYER 2 may be parallel to each other. The plurality of second layers LAYER 2 may be repeated every second length S2 in the first direction X. The second layer LAYER 2 may have the second width W2.

The first layer LAYER 1 and the second layer LAYER 2 may be electrically connected to each other through the via VIA. First layers 921 and 923 adjacent to each other in the second direction Y may be electrically connected to the second layer LAYER 2 through vias 901 and 902. Here, the vias 901 and 902 may be disposed on the same layer and may be adjacent to each other in the second direction Y.

On the other hand, vias positioned on the same layer need to be spaced apart by a certain distance. For example, the minimum distance that the vias positioned on the same layer need to be spaced apart is previously determined as a minimum spacing rule according to a design rule that may be defined by a semiconductor process, and the vias positioned on the same layer are spaced apart from each other by more than the distance according to the minimum spacing rule.

According to the comparative example, because the second layer LAYER 2 extends linearly in the second direction Y, positions of the vias 901 and 902 in the first direction X may be the same as each other. On the first layers 921 and 923 adjacent to each other in the second direction Y, a spacing distance 910 of the vias 901 and 902 disposed on the same layer in the second direction Y may be less than the previously determined minimum spacing distance of the vias. Accordingly, on the first layers 921 and 923 adjacent to each other in the second direction Y, the vias 901 and 902 of the same layer may not be disposed at the same position in the first direction X. Because the first and second widths W1 and W2 of a lower layer (e.g., the first layer LAYER 1) and an upper layer (e.g., the second layer LAYER 2) are different from each other, and the first and second lengths S1 and S2 between the lower and upper layers are different from each other, the IC 900 including the second layer LAYER 2 according to the comparative example has a problem in that an arrangement of the vias 901 and 902 is restricted.

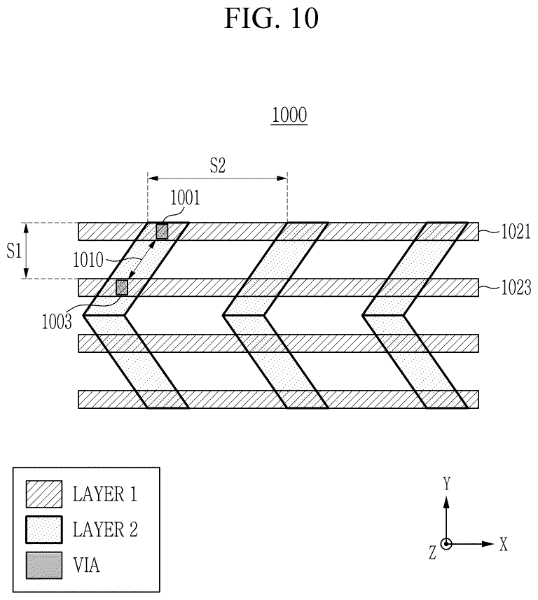

FIG. 10 is a layout diagram of a partial region of an IC 1000 according to some embodiments. For convenience of description, descriptions that are redundant with those of FIG. 9 are omitted here.

In some embodiments, the IC 1000 may include the second layers LAYER 2 stacked on the first layers LAYER 1 in the vertical direction Z. The second layer LAYER 2 according to some embodiments may be electrically connected to the first layer LAYER 1 through the vias VIA.

According to some embodiments, first layers 1021 and 1023 adjacent to each other in the second direction Y may be electrically connected to the second layer LAYER 2 through vias 1001 and 1003. According to the structure of the second layer LAYER 2 according to some embodiments, positions of the vias 1001 and 1003 disposed on the same layer and adjacent to each other in the second direction Y may be different from each other in the first direction X. Accordingly, on the first layers 1021 and 1023 adjacent to each other in the second direction Y, a spacing distance 1010 of the vias 1001 and 1002 disposed on the same layer and adjacent to each other in the second direction Y may be greater than the distance 910 of FIG. 9 according to the comparative example. The spacing distance 1010 of the vias 1001 and 1002 disposed on the same layer and adjacent to each other in the second direction Y according to some embodiments may be greater than a previously determined minimum spacing distance of the vias.

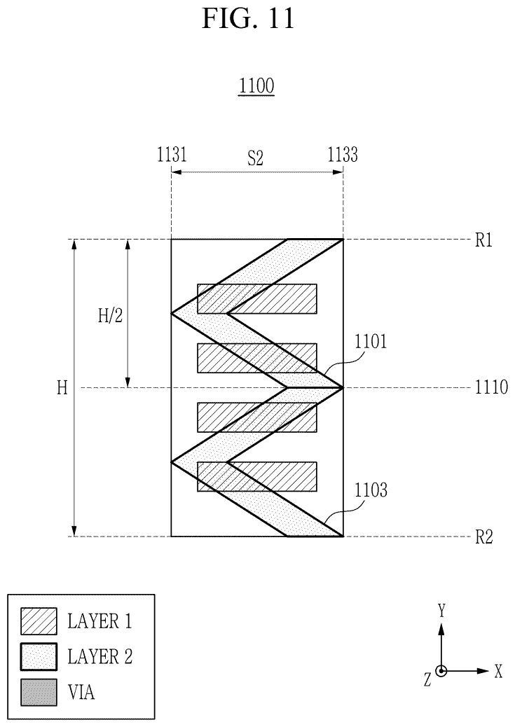

FIG. 11 is a layout diagram of a standard cell 1100 and layers on the standard cell 1100 according to some embodiments. For convenience of description, descriptions that are identical or similar to those described above are omitted here.

Referring to FIG. 11, the standard cell 1100 may be disposed along the first row R1 and the second row R2. The standard cell 1100 may be a single row cell.

In some embodiments, the standard cell 1100 may include a plurality of first layers LAYER 1 extending in the first direction X, and the second layer LAYER 2 may be stacked on the first layers LAYER 1.

The second layer LAYER 2 according to some embodiments may include a first unit layer 1101. The unit layer 1101 may extend from a first vertical line 1131 to a second vertical line 1133 in the second direction Y. A length of the unit layer 1101 in the second direction Y may be equal to half H/2 of spacing H of the first and second rows R1 and R2 adjacent in the second direction Y. The unit layer 1101 may be symmetric in the second direction Y.

The second layer LAYER 2 according to some embodiments may include a plurality of first and second unit layers 1101 and 1103 repeatedly disposed in the second direction Y. The second layer LAYER 2 on the standard cell 1100 may extend from the first row R1 to the second row R2. The second layer LAYER 2 on the standard cell 1100 may be symmetric in the second direction Y. Meanwhile, the second length S2 between the first vertical line 1131 and the second vertical line 1133 may be equal to 1 cpp, but is not limited thereto.

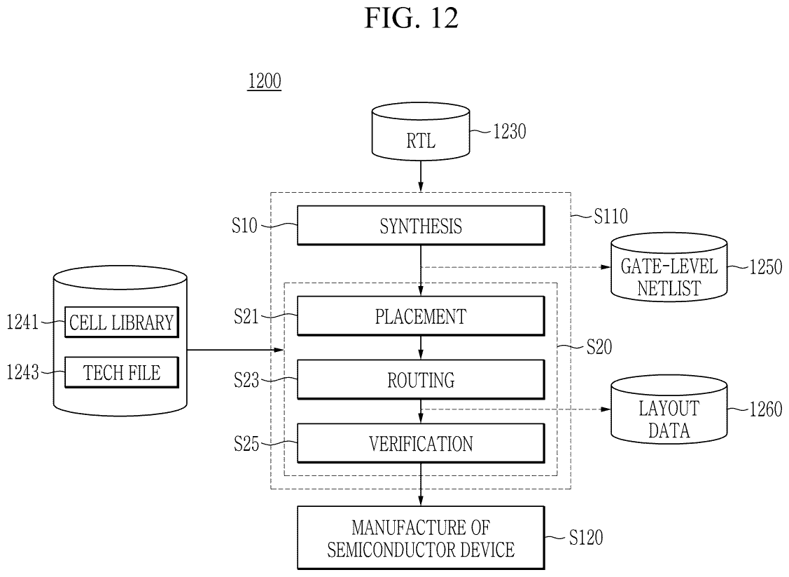

FIG. 12 is a flowchart for explaining a method 1200 of designing and manufacturing an IC according to some embodiments.

Referring to FIG. 12, the method 1200 of designing and manufacturing the IC may include a design step S110 of the IC and a manufacturing step S120 of the IC. The design step S110 of the IC is a step of generating a gate level netlist 1250, designing layout data 1260 for the IC, and verifying the layout data 1260, which may be performed in a design tool of the IC for designing and verifying the IC.

The design step S110 of the IC may include a logic synthesis step S10 and a physical design step S20. The logic synthesis step S10 may refer to a step of generating the gate level netlist 1250 from RTL data 1230. For example, the IC design tool (for example, a logic synthesis tool) may perform a logic synthesis operation of generating the gate level netlist 1250 (hereinafter, referred to as a “netlist”) from the RTL data 1230 written as a VHSIC hardware description language (VHDL) and a hardware description language (HDL) such as Verilog. The netlist 1250 represents a connection relationship between cells in the IC, and may refer to a logical circuit schematic diagram.

The physical design step S20 may include a placement step S21, a routing step S23, and a verification step S25. The IC design tool may receive a cell library 1241 and a tech file 1243 and perform each step based on the cell library 1241 and the tech file 1243.

In the placement step S21, standard cells may be placed. For example, the IC design tool (e.g., a P&R tool) may place the standard cells used in the netlist 1250. The IC design tool may place the standard cells along a predefined row based on information about the standard cells stored in the cell library 1241. The cell library 1241 may include layout information such as a height, a size, or geometric information of patterns forming the standard cell, and characteristic information such as delay and leakage current of the standard cell. Here, the standard cell may include logical devices such as AND, OR, inverters, and memory devices such as flip-flops. The standard cell may be implemented by at least one transistor, a metal oxide semiconductor field effect transistor (MOSFET), a finFET, etc., but is not limited thereto.

In the routing step S23, pins of the standard cells may be routed. For example, the IC design tool may electrically connect the pins of the standard cells placed in the placement step S21 based on the connection relationship of the standard cells of the netlist 1250.

The IC may include layers electrically connecting the standard cells. Specifically, the IC may include layers stacked in a vertical direction. The structure of the layers stacked on the IC may be the same as or similar to the structure of routing layers of FIG. 1. The layers may be connected through vias formed on the layers, and the layers and the vias may electrically connect the pins of the standard cells.

The IC design tool may generate a plurality of layers based on information stored in the tech file 1243. The tech file 1243 may include information about the plurality of layers and a plurality of vias. For example, the tech file 1243 may define names of layers and vias, width, spacing, or area of metal layers and vias according to design rules.

In some embodiments, the IC design tool may place a second layer, which is a vertical layer, as a unit layer. For example, a first unit layer positioned in a second direction in a row extending in a first direction may extend in a fourth direction in which the first direction and the second direction intersect, and a second unit layer positioned in a direction opposite to the second direction in a row extending in the first direction may extend in a fifth direction in which the first direction and the direction opposite to the second direction intersect. The first unit layer and the second unit layer may be symmetrical to each other in the second direction with respect to the row. The second layer may include the first unit layer and the second unit layer alternately disposed in the second direction. Among a plurality of vias electrically connected to a plurality of first layers extending in the first direction and one second layer extending in the second direction, positions of vias adjacent to each other in the second direction may be different from each other in the first direction. According to some embodiments, the second layer extending between cell boundaries of the standard cell in the first direction may be symmetric in the second direction on the standard cell.

The IC design tool may generate the layout data 1260 defining the placed standard cells and the generated plurality of layers and vias. The layout data 1260 may have a format such as GDSII, and may include geometric information of the standard cells and the plurality of layers and vias.

The verification step S25 may be a step of verifying and modifying the generated layout. Items to be verified may include a static timing analysis (STA) that verifies whether the layout satisfies the timing condition of design, a design rule check (DRC) that verifies whether the layout properly complies with the design rule, an electronic rule check (ERC) that verifies whether the layout is properly made inside without an electrical disconnection, a layout versus scheme (LVS) that verifies whether the layout matches the netlist, etc.

The manufacturing step S120 of the IC may include a plurality of steps for manufacturing a mask and forming a semiconductor package.

The manufacturing step S120 of the IC may include a step of generating mask data for forming various patterns of the plurality of layers by performing an optical proximity correction (OPC) on the layout data 1260 generated in the design step S110 of the IC, and a step of manufacturing the mask by using the mask data. In the manufacturing step S120 of the IC, various types of exposure and etching processes may be repeatedly performed. Through these processes, shapes of patterns configured when designing the layout may be sequentially formed on a silicon substrate.

In addition, in the manufacturing step S120 of the IC, a packaging process of mounting a semiconductor device generated by the IC on a PCB and molding the semiconductor device with a molding material may be performed. Through the packaging process, the semiconductor device may be flipped or bonded on a substrate by using a plurality of contact members.

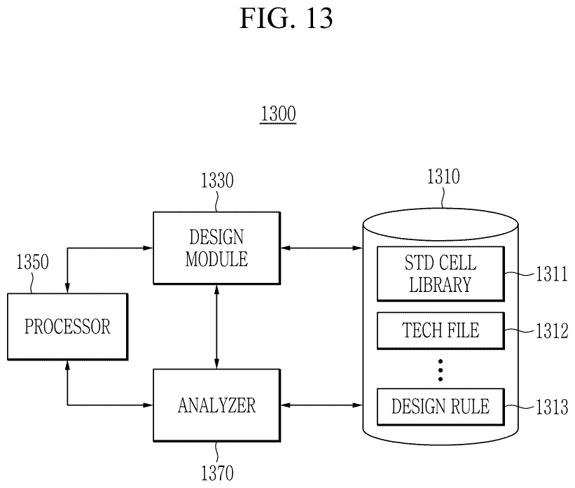

FIG. 13 is a diagram schematically illustrating a design system 1300 of an IC according to some embodiments.

The design system 1300 may include a storage device 1310, a design module 1330, a processor 1350, and an analysis module 1370. The design system 1300 of FIG. 13 may perform at least some of design operations of the IC described in the design method of the IC described with reference to FIGS. 1 to 8 and 10 to 12. The design system 1300 may be implemented as an integrated device, and accordingly, may be referred to as a design device. The design system 1300 may be provided as a dedicated device for designing the IC, but may be a computer for driving various simulation tools or design tools.

According to some embodiments, the storage device 1310 may include a standard cell library 1311, a tech file 1312, and a design rule 1313. According to some embodiments, the standard cell library 1311 may include layout information of a standard cell, and the tech file 1312 may include information about a plurality of layers within the IC. The standard cell library 1311, the tech file 1312, and the design rule 1313 in the storage device 1310 may be provided from the storage device 1310 to the design module 1330 and the analysis module 1370. The number of cell libraries included in the storage device 1310 may be variously changed.

The design module 1330 according to some embodiments may receive the standard cell library 1311, the tech file 1312, and the design rule 1313 from the storage device 1310 to perform the design operations of the IC of FIGS. 1 to 8 and 10 to 12. In some embodiments, the design module 1330 may perform a placement operation on standard cells by using the standard cell library 1311 and may perform a routing operation on the standard cells after generating a plurality of layers according to the tech file 1312. The design module 1330 according to some embodiments may place a second layer, which is a vertical layer, among the plurality of layers as a unit layer. Specifically, unit layers symmetrical in a second direction may be alternately placed with respect to a row in which the standard cells are placed. Meanwhile, the unit layer of the second layer according to some embodiments may extend by a previously determined length in the second direction between a first vertical line and a second vertical line spaced apart in a first direction. Here, spacing between the first vertical line and the second vertical line may be equal to 1 cpp. In addition, in the present disclosure, the term “module” may refer to software, hardware such as field programmable gate array (FPGA), or application specific integrated circuit (ASIC), or a combination of software and hardware.

The processor 1350 may be used for the design module 1330 and the analysis module 1370 to perform calculations. For example, the processor 1350 may include a micro-processor, an application processor (AP), a digital signal processor (DSP), a graphic processing unit (GPU), etc. Only one processor 1350 is illustrated in FIG. 13, but the design system 1300 may include a plurality of processors according to embodiments. The processor 1350 may include a cache memory to improve computational performance.

The analysis module 1370 may analyze and verify a layout generated by the design module 1330 during or after performing the design operations of the IC of FIGS. 1 to 8 and 10 to 12. In some embodiments, the analysis module 1370 may analyze and verify whether a distance between vias adjacent in the second direction and positioned in the same layer satisfies the minimum spacing distance according to the design rule, based on the design rule 1313 received from the storage device 1310. Specifically, the analysis module 1370 may analyze and verify whether the distance between vias adjacent in the second direction satisfies the minimum spacing distance according to the design rule, among a plurality of vias electrically connected to a plurality of first layers extending in the first direction and one second layer extending in the second direction. In addition, the analysis module 1370 may analyze and verify whether the standard cells and the plurality of layers connecting the standard cells satisfy the design rule, based on the design rule 1313 received from the storage device 1310.

Many alterations and modifications may be made by those having ordinary skill in the art, given the benefit of present disclosure, without departing from the spirit and scope of the inventive concept(s). Therefore, it must be understood that the illustrated embodiments have been set forth only for the purposes of example, and that it should not be taken as limiting the inventive concept(s) as defined by the following claims. The following claims, therefore, are to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the inventive concept(s).

What is claimed is:

1. An integrated circuit (IC) comprising:
a plurality of first layers extending in a first direction and arranged in a second direction perpendicular to the first direction; and
a second layer comprising:
a first unit layer extending in a third direction intersecting the first direction and the second direction; and
a second unit layer connected to the first unit layer and extending in a fourth direction symmetrical to the third direction with respect to the first direction, and electrically connected to one layer of the plurality of first layers through a first via positioned on the one layer.

2. The IC of claim 1, wherein:
the first unit layer extends in the third direction between a first position and a second position spaced apart by a first length in the first direction; and
the second unit layer extends in the fourth direction between the first position and the second position in the first direction.

3. The IC of claim 2, wherein:
the first length is 1 contacted poly pitch (cpp).

4. The IC of claim 1, wherein:
the third direction is a direction inclined at a predetermined angle from the first direction to the second direction, and the predetermined angle is between 0° and 90°.

5. The IC of claim 1, wherein:
the second layer includes at least one first unit layer and at least one second unit layer alternately disposed in the second direction.

6. The IC of claim 1, further comprising:
a standard cell including a first cell boundary extending in the first direction and a second cell boundary spaced apart from the first cell boundary in the second direction and extending in the first direction.

7. The IC of claim 6, wherein:
the first unit layer and the second unit layer are disposed in the same number within the standard cell.

8. The IC of claim 6, wherein:
the standard cell is a single row cell.

9. The IC of claim 6, wherein:
the standard cell is a multi-row cell.

10. The IC of claim 6, wherein:
a length of each of the first unit layer and the second unit layer in the second direction is ½n of a length between the first cell boundary and the second cell boundary in the second direction, wherein n is a positive integer.

11. The IC of claim 1, wherein:
the second layer is electrically connected to another layer of the plurality of first layers through a second via positioned on the another layer.

12. The IC of claim 11, wherein:
positions of the first via and the second via are different from each other in the first direction.

13. An integrated circuit (IC) comprising:
a standard cell comprising a plurality of cell boundaries extending in a first direction;
a first layer extending in the first direction between a first cell boundary and a second cell boundary among the plurality of cell boundaries; and
a second layer extending from a first point of the first cell boundary to a second point spaced apart from the first point by a first length in the first direction and positioned between the first cell boundary and the second cell boundary in a second direction perpendicular to the first direction, wherein the second layer is symmetrical in the second direction in the standard cell, and the second layer is positioned on the first layer.

14. The IC of claim 13, wherein:
the second point is positioned in a middle between the first cell boundary and the second cell boundary in the second direction.

15. The IC of claim 13, wherein:
the first length is 1 contacted poly pitch (cpp).

16. The IC of claim 13, wherein:
a width of the second layer is less than the first length.

17. The IC of claim 13, further comprising:
a third layer positioned on the same layer as the second layer, spaced apart from the second layer in the first direction, and having the same structure as the second layer.

18. The IC of claim 17, wherein:
a spacing length between the second layer and the third layer in the first direction is the same as the first length.

19. An integrated circuit (IC) comprising:
a first standard cell;
a second standard cell adjacent to the first standard cell in a first direction;
a first layer extending in a second direction perpendicular to the first direction on the first standard cell and the second standard cell; and
a second layer comprising:
a plurality of first unit layers positioned on the first layer in the first standard cell and the second standard cell and extending in a third direction between the first direction and the second direction; and
a plurality of second unit layers symmetrical with the plurality of first unit layers in the first direction and alternately disposed with the plurality of first unit layers in the first direction.

20. The IC of claim 19, wherein:
a height of the first standard cell in the first direction is different from a height of the second standard cell.
